(19) United States
(12) Patent Application Publication
(10) Pub. No.: US 2015/0325527 A1
(43) Pub. Date: Nov. 12, 2015

(54) RADIUSED ALIGNMENT POST FOR SUBSTRATE MATERIAL

(71) Applicant: Hewlett-Packard Development Company, LP., Fort Collins, CO (US)

(72) Inventors: Paul Kessler Rosenberg, Palo Alto, CA (US); Michael Tan, Palo Alto, CA (US); Sagi Mathai, Palo Alto, CA (US)

(21) Appl. No.: 14/764,005

(22) PCT Filed: Jan. 28, 2013
(86) PCT No.: PCT/US2013/023422

§ 371 Date: Jul. 28, 2015

(51) Int. Cl. H01L 23/544; H01L 21/82; H01L 25/00; H01L 21/3213

(52) U.S. Cl. CPC H01L 23/544; H01L 21/32136; H01L 21/82; H01L 25/50; H01L 2223/54426

(57) ABSTRACT

A method includes growing a substrate material that includes an integrated circuit. The method includes forming an alignment post on the substrate material and forming a radiused top portion on the alignment post to enable alignment of a connector to the substrate material.

### BACKGROUND

Integrated circuits are typically formed on silicon substrate materials such as a wafer. Various chemical & lithographic processes can be applied to the wafer to form electrical circuit components and signal traces for the respective circuits. After the circuits and signal traces are formed, the wafer can be cut into individual integrated circuits that can then be packaged and utilized in a given electrical design. The signal traces are typically connected to pins of the packaged integrated circuit where the pins then interface to other peripheral circuits outside the package in a given application. In pure electrical designs, there is no need to couple the signal traces inside the packaged integrated circuit to any other outside connection other than the respective pins. In an electro-mechanical design, where mechanical couplings may be needed to the substrate, there may be an additional requirement to couple individual circuit elements of the integrated circuit to external components other than at the pins. Such coupling requirements can cause problems with making proper signal connections between the substrate and the external components.

### BRIEF DESCRIPTION OF THE DRAWINGS

FIG. 1 illustrates an example of a substrate material having an alignment post formed thereon to enable alignment with a connector.

FIG. 2 illustrates an example of alignment posts formed on a substrate material that are employed to align a connector to a glass substrate material coupled to the substrate material.

FIG. 3 illustrates an example of a substrate material having an alignment post formed thereon via a DRIE process to enable alignment with a connector.

FIG. 4 illustrates an example of a substrate material having an alignment post formed thereon via an electroplating process to enable alignment with a connector.

FIG. 5 illustrates an example of a substrate material having an alignment post formed thereon via application of a secondary material and photolithography process to enable alignment with a connector.

FIG. 6 illustrates example method for forming an alignment post on a substrate material.

### DETAILED DESCRIPTION

An alignment post can be formed on a substrate material to enable smooth and efficient alignment of the substrate material to other structures such as connectors and/or other substrates, for example. The substrate material can be a silicon substrate in one example and can be precisely aligned with external signals from a connector via one or more alignment posts. The alignment post can be formed on to the substrate material via various processes. In one example, an etching process can be applied to the substrate material to form a cylindrical portion of the alignment post that is left attached to the substrate material after etching. A radiused top portion can be applied to the cylindrical portion of the alignment post to enable a smooth lead-in for the alignment post to be precisely mated to a mating cavity on the connector. In one example, multiple alignment posts are formed on the substrate material and utilized to align the substrate material with another substrate material where signals can be exchanged between the respective substrates and/or connector after the alignment.

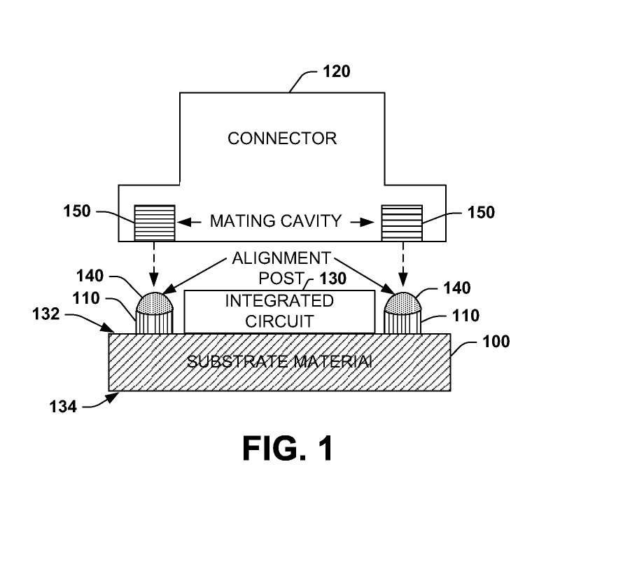

FIG. 1 illustrates an example of a substrate material 100 having an alignment post 110 formed thereon to enable alignment with a connector 120. The substrate material 100 may include an integrated circuit 130 which can be formed on a top surface 132 and/or bottom surface 134 of the substrate. Other discrete electrical and/or optical components may also be attached to the top surface 132 and/or bottom surface 134 of the substrate material 100. The substrate material 100 is typically a semiconductor material such as silicon although other substrate materials are possible (e.g., germanium). The alignment post 110 can be a single alignment post in some applications or provided as multiple alignment posts in other applications. Typical lithography processes produce features, such as a cylinder, with a flat top surface. Further considering a cylindrical feature, the transition from the top surface of the cylinder to the vertical cylinder walls occurs abruptly, with a sharp transitional edge. It is difficult to insert a cylindrical post on one component into a cylindrical hole on a second component in the case where both post and hole features have a sharp transition between their top and side surfaces. This is also true in the case that the cylinder diameter is only slightly smaller than the hole diameter when it is desirable to achieve precise alignment between the two connecting components. The mating process is made easier by reducing the sharpness of this transition by incorporating a radius or angle (chamfer) at the transition. As shown, a radiused top portion 140 is provided on the alignment post 110 to facilitate the transition.

The alignment post 110 includes a cylindrical portion formed on the substrate material 100, wherein the alignment post includes a radiused top portion 140 formed on the cylindrical portion. The radiused top portion 140 of the alignment post 110 facilitates the engagement between a mating cavity 150 of the connector 120 and the cylindrical portion of the alignment post 110. Incorporation of the radiused top portion 140 creates a larger ‘capture zone’ between the mating components 120 and the substrate material 100. The central axes of the alignment post cylinder and the mating cavity 150 can be displaced from each other by a larger distance than if the radiused top portion 140.

As shown, mating of the connector 120 to the substrate material 100 can be achieved via the mating cavity 150 on the connector that is guided over the alignment posts 110 and the radiused top portion 140. Such radiusing on the alignment post 110 can be referred to as a lead-in for the alignment post to be mated to the mating cavity 150 of the connector 120. The connector 120 can also include optical waveguides for routing optical signals.

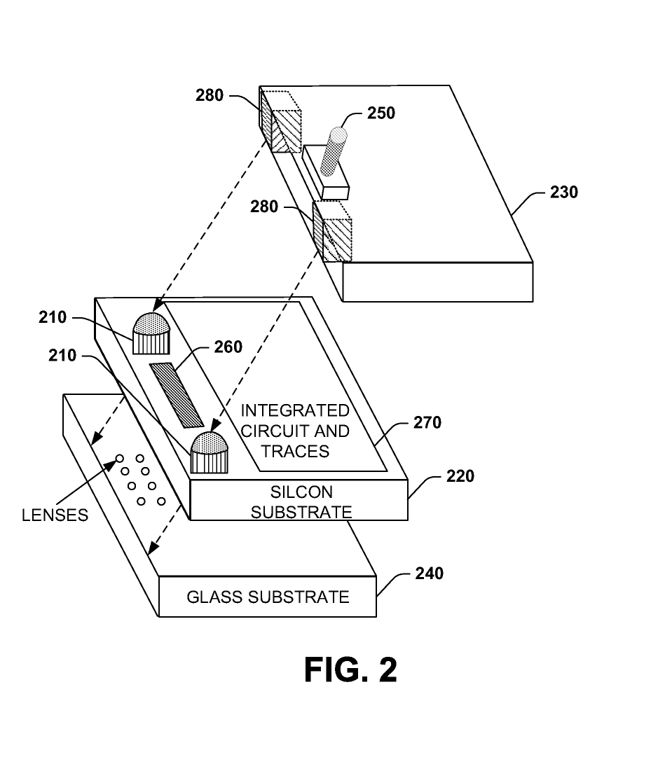

In some examples, alignment between the connector 120 and the substrate 100 can achieve alignment of electrical contacts on the connector that coupled to signal traces on the substrate. In another example, optical signals, for example carried in optical fibers, in the connector 120 could be mated to optical components, such as laser diodes or photodetectors, formed on the substrate material 100. In yet another example as will be shown and described below with respect to FIG. 2, another substrate material such as a glass substrate could be coupled to the substrate material 100. A cavity could be formed in the substrate material 100 to allow optical signals to flow between the connector 120 and the glass substrate, wherein the alignment posts 110 on the substrate material allow alignment of optical signals from the connector to be aligned with lenses formed on the glass substrate.

Several methods can be provided for forming the alignment posts 110 and radiused top portions 140. This can include growing a substrate material 100 that includes the integrated circuit 130. After growing the substrate, the methods can include forming the alignment post 110 on the substrate material 100 via various processes described below and then forming the radiused top portion 150 on the alignment post to enable alignment of the connector 120 to the substrate material 100. In one example, methods can include applying a liquid polymer on to the alignment post 110 to form the radiused top portion 140. In another example, this can include applying a liquid solder on to the alignment post 110 to form the radiused top portion 140. Whether polymer, solder, or other radiusing material is employed, material rheology is controlled such that the radiusing material, flows to the edge of the alignment post 110 but not further as surface tension and other contact forces acting between the material and the post cause the radiusing material to form the desired shape on top of the post.

The alignment posts 110 can be formed according to various methods. In one example, the methods can include etching the substrate material 100 to form the alignment post 110. For example, this could include utilizing a Deep Reactive Ion Etching (DRIE) for etching the substrate material 100 to form the alignment post 110. In another post construction process, methods can include lithographic masking and patterning of a surface coating such as polyimide or BCB polymer, followed by electroplating the substrate material to form the alignment post. This can include multiple electroplating processes to grow a cylindrical shape on top of the substrate material 100. In another type of post construction process, methods can include applying an epoxy to the substrate material 100 to form the alignment post. This can further include shaping the epoxy via a photolithography process, for example. As will be shown below with respect to FIG. 2, methods can include forming a cavity in the substrate material 100 to allow light to pass through the cavity via the connector 120. This can include aligning the substrate material 100 to another substrate material (e.g., a glass substrate material) via the alignment post 110, wherein light signals from the glass substrate material can interface with the integrated circuit 130 of the substrate material 100.

FIG. 2 illustrates an example of alignment posts 210 formed on a substrate material 220 that are employed to align a connector 230 to a glass substrate material 240 coupled to the substrate material. The connector 230 can include an optical cable 250 for routing optical signals through a cavity 260 formed in the substrate material 220. Lenses can be formed on the glass substrate 240 to route the optical signals to various locations on the glass substrate 240. In one example, the lenses can route the optical signals such that the signals couple to optical components such as photodetectors integrated into or attached to the substrate 220. The lenses can also transmit the optical signals through the glass substrate 240 to optical components residing on the far (non-lens) side of the glass substrate. The integrated circuit and traces 270 can reside on top of the substrate material and/or on the bottom of the substrate material and between the glass substrate 240. Mating cavities 280 in the connector 230 can be aligned with the alignment posts 210. The mating cavities 280 can be rectangular in one example or cylindrical cavities in another example. In this manner, light signals from the optical cable 250 can be aligned via the alignment posts 210 through the cavity 260 and to the lenses on the glass substrate 240.

As discussed above, the process of Deep Reactive Ion Etching (DRIE) can be used to fabricate a variety of useful geometries in silicon, including negative shapes such as holes, trenches, pits, and positive shapes such as the alignment posts 210. In this example, a combination of posts and/or trenches can be fabricated in the silicon substrate 220 in order to provide a precision alignment interface for attachment of one or more optical fibers or connectors. The silicon substrate 220 can be bonded to the glass substrate 240 on to which are formed lenses and electrical traces for attaching and aligning active optical devices such as lasers or photodiodes, for example. The silicon cavity 260 provides a clearance through which light signals can pass through the silicon substrate 220. The alignment posts 210 are previously formed and located with respect to the glass lenses. They are used to provide alignment for the optical connector 230 carrying optical fibers which communicate with the active devices electrically connected to the glass substrate 240.

The DRIE process can form precise and consistent features, such as alignment posts 210 with diameter variation on the order of a few microns or less. The alignment posts 210 can naturally have a flat top surface due to the aforementioned fabrication processes. As such, the alignment posts 210 are not optimized to help guide the optical connector 230 into position during the alignment process. In order to provide guidance to the connector 230, the alignment posts 210 should have a radiused top portion as shown and discussed above. The DRIE process may not be optimized to create these radiused geometries. It is also desirable to maintain a relatively long cylindrical post shape of constant diameter in order to achieve precise alignment between the post and the cylindrical cavities 280 in the mating optical connector 230. By utilizing some of the post length for radius (commonly referred to as lead-in), the alignment effectiveness may be reduced. The alignment post can be lengthened in order to provide more material for alignment and lead-in. But this increases the time required for the post fabrication process and its cost.

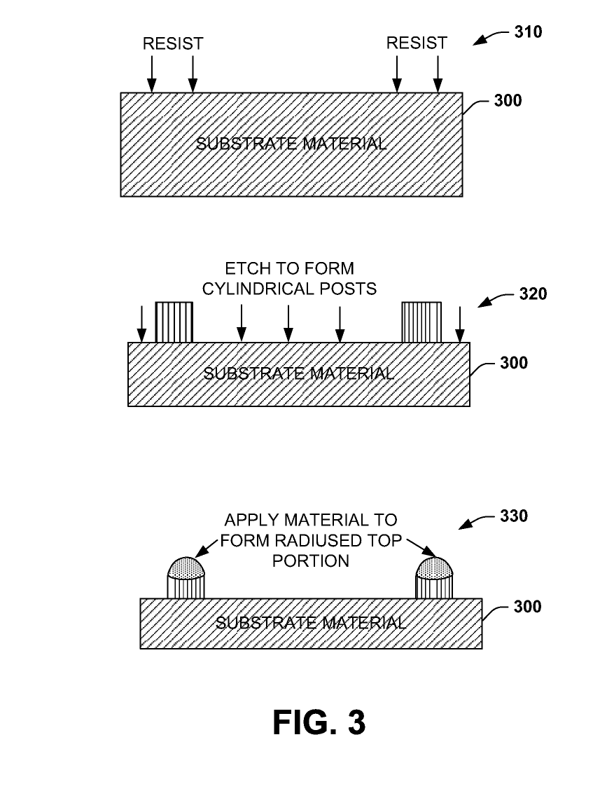

The systems and methods described herein form a nearly ideal lead-in surface in an efficient manner by dispensing a precise amount of liquid polymer or liquid solder (or applying solid material that can be liquefied in a heating process) on to the top surface of the alignment posts 210 such that this material will solidify into a curved or radiused lead-in surface for the post. The polymer can be a melted thermoplastic, or uncured thermo-set plastic, for example. The solder can be applied as a paste, preformed, sputtered, or electro-plated onto the top of the alignment post 280. By controlling the composition and quantity of the polymer or solder material, the lead-in can naturally flow out to the post perimeter. Energy considerations can cause the material to assume a favorable curved surface shape. In the case of polymer material, suitable chemistry can result in the formation of a strong bond between the polymer and the top surface of the alignment post 280 in a manner that is suited to withstanding the process of guiding optical connectors 230 during multiple connection cycles. FIGS. 3, 4, and 5 and related discussion will illustrate alternative examples for constructing the alignment posts 280 on to the silicon substrate 220.

FIG. 3 illustrates an example of a substrate material 300 having an alignment post formed thereon via a Deep Reactive Ion Etch (DRIE) process to enable alignment with a connector. A first stage of forming the alignment post involves applying resist material to the substrate such as shown by resist arrows at 310. Such resist can be applied in a circular pattern such that after a subsequent etching on the substrate, a cylindrical post remains after the etching. At 320, a DRIE etching process is applied to the substrate wherein arrows indicate the direction for the etch pattern. After etching, cylindrical posts are formed on the substrate material 300 in the areas where the resist was previously applied. At 330, the cylindrical posts have material applied to form radiuses at the top of the cylindrical alignment posts. As described previously, such radiusing material can be applied from a liquid polymer or liquid solder, for example.

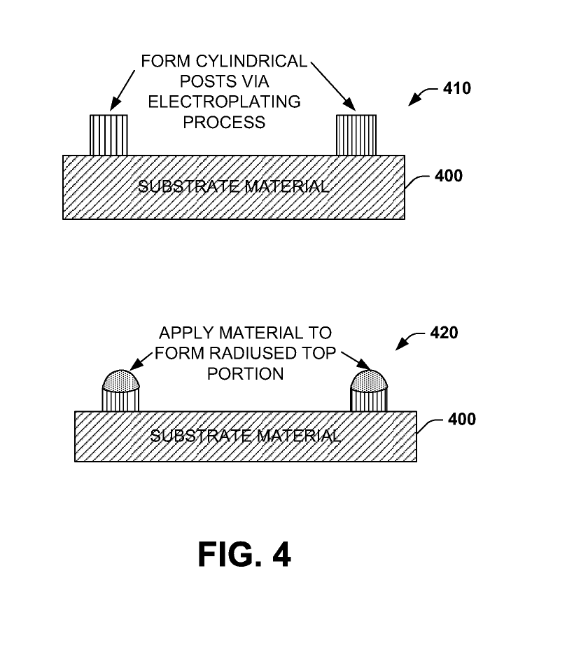

FIG. 4 illustrates an example of a substrate material 400 having an alignment post formed thereon via an electroplating process to enable alignment with a connector. At 410, a substrate material 400 is shown having electroplated posts formed thereon. Such electroplating can be formed in a continuous process to grow a cylindrical post on top of the substrate material 400, for example. Typically, this process employs a lithographically formed mold, made of resist or other polymer into which is formed the negative shape of the posts. The plating can be built up inside the negative shapes formed in the polymer to create the posts. This process often referred to as electroforming. At 420, the cylindrical posts created from electroplating the substrate have material applied to form radiuses at the top of the cylindrical alignment posts. Similar to the example of FIG. 3, such radiusing material can be applied from a liquid polymer or liquid solder, for example.

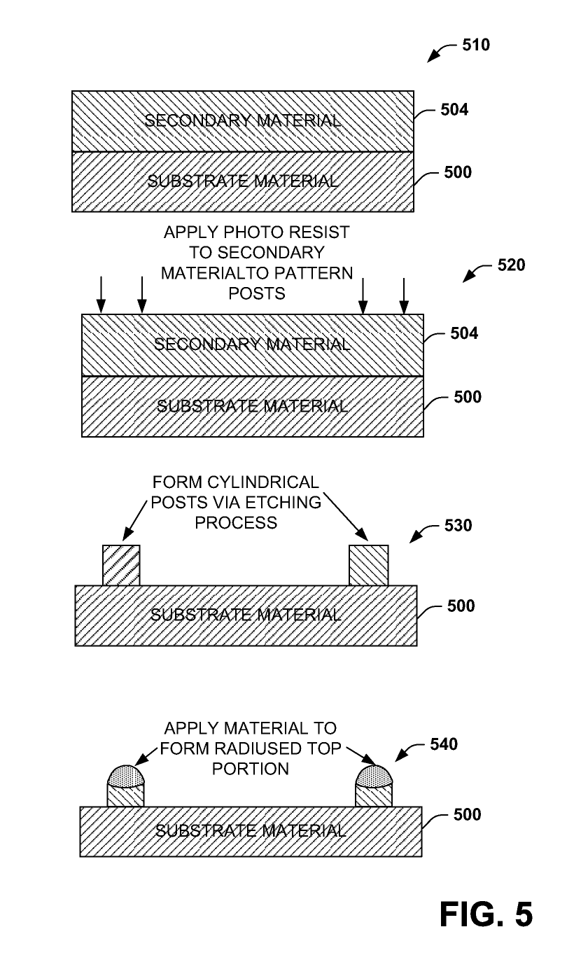

FIG. 5 illustrates an example of a substrate material 500 having an alignment post formed thereon via application of an epoxy and photolithography process to enable alignment with a connector. In this example, a secondary material 504 can be formed on top of the substrate material 504. Such secondary material 504 could include an adhesive such as epoxy for example, or in another example, polyimide epoxy. At 520, a photo resist can be applied to the secondary material 504, wherein the photo resist forms an etching pattern for a cylindrical structure. At 530, cylindrical posts are formed by applying an etching process to secondary material 504 and to form the posts. At 540, the cylindrical posts created at 530 have material applied to form radiuses at the top of the cylindrical alignment posts formed from epoxy and subsequent etch. Similar to the example of FIGS. 3 and 4, such radiusing material can be applied from a liquid polymer or liquid solder, for example.

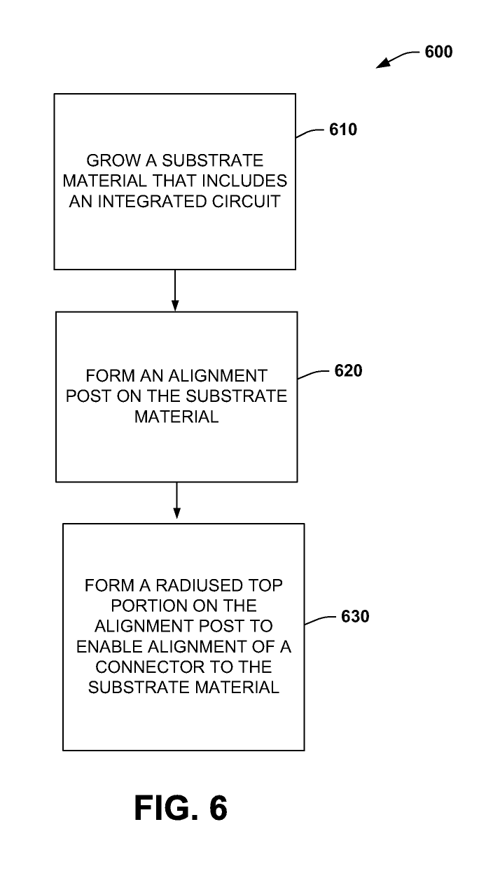

In view of the foregoing structural and functional features described above, an example method will be better appreciated with reference to FIG. 6. While, for purposes of simplicity of explanation, the example method of FIG. 6 is shown and described as executing serially, it is to be understood and appreciated that the present examples are not limited by the illustrated order, as some actions could in other examples occur in different orders and/or concurrently from that shown and described herein. Moreover, it is not necessary that all described actions be performed to implement a method.

FIG. 6 illustrates example method 600 for forming an alignment post on a substrate material. At 610, the method 600 includes growing a substrate material that includes an integrated circuit (e.g., substrate material 100 and integrated circuit of FIG. 1). The method 600 includes forming an alignment post on the substrate material at 620 (e.g., alignment post 110 of FIG. 1). The method 600 includes forming a radiused top portion on the alignment post to enable alignment of a connector to the substrate material (e.g., radiused top portion 140 of FIG. 1). The method 600 can also include applying a liquid polymer on to the alignment post to form the radiused top portion. In another example, the method can include applying a liquid, or solid, solder on to the alignment post to form the radiused top portion.

The method 600 can also include etching the substrate material to form the alignment post. This can include utilizing a Deep Reactive Ion Etching (DRIE) for etching the substrate material to form the alignment post. In another example, the method 600 can include electroplating the substrate material to form the alignment post. In another example, the method 600 can include applying an epoxy to the substrate material to form the alignment post. This can include shaping the epoxy via a photolithography process. The method 600 can also include forming a cavity in the substrate material to allow light to pass through the cavity. This can include aligning the substrate material to a glass substrate material via the alignment post, wherein light signals from the glass substrate material can interface with the integrated circuit of the substrate material.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

What is claimed is:

1. A method comprising:
growing a substrate material that includes an integrated circuit;
forming an alignment post on the substrate material; and
forming a radiused top portion on the alignment post to enable alignment of a connector to the substrate material.

2. The method of claim 1, further comprising applying a liquid polymer on to the alignment post to form the radiused top portion.

3. The method of claim 1, further comprising applying solder as a liquid or solid on to the alignment post to form the radiused top portion.

4. The method of claim 1, further comprising etching the substrate material to form the alignment post.

5. The method of claim 4, further comprising utilizing a Deep Reactive Ion Etching (DRIE) for etching the substrate material to form the alignment post.

6. The method of claim 4, further comprising electroplating the substrate material to form the alignment post.

7. The method of claim 4, further comprising applying an epoxy to the substrate material to form the alignment post.

8. The method of claim 7, further comprising shaping the epoxy via a photolithography process.

9. The method of claim 1, further comprising forming a cavity in the substrate material to allow light to pass through the cavity.

10. The method of claim 9, further comprising aligning the substrate material to an optically transparent substrate material via the alignment post, wherein light signals can be transmitted through the optically transparent substrate material to components on either side of the substrate material.

11. An apparatus comprising:
a first substrate material that includes electronic and optical components in discrete form or integrated form; and
an alignment post comprising a cylindrical portion formed on the substrate material, the alignment post includes a radiused top portion formed on the cylindrical portion, wherein the radiused top portion of the alignment post provides an alignment guide for mating a connector to the substrate material.

12. The apparatus of claim 11, further comprising an optically transparent substrate that is bonded to the first substrate material, wherein a cavity is formed in the first substrate material to allow light to pass though the first substrate material.

13. The apparatus of claim 12, wherein the alignment post aligns lenses on the transparent optical substrate with optical waveguides in the connector.

14. The apparatus of claim 13, wherein the alignment post is formed via an etching process, an electroplating process, or a polymer development photolithography process.

15. An apparatus comprising:
a first silicon substrate material that includes integrated or discrete electronic components and circuitry, the silicon substrate material having a cavity formed therein to allow light to pass from an optical connector through the substrate material;
an optically transparent substrate material bonded to the first silicon substrate material, wherein the optically transparent substrate material provides lenses to receive the light that is passed from the optical connector through the first substrate material; and
a plurality of alignment posts, each alignment post comprising a cylindrical portion formed on the first silicon substrate material, each alignment post includes a radiused top portion formed on the respective cylindrical portion, wherein the radiused top portion of the alignment posts provides alignment for mating the connector to the first silicon substrate material and the optically transparent substrate material.
